(19) United States
(12) Patent Application Publication
(10) Pub. No.: US 2013/0280427 A1
(43) Pub. Date: Oct. 24, 2013

(54) Tube Reactor for Chemical Vapor Deposition

(71) Applicants: Xuesong Li, Yorktown Heights, NY (US); Yu-Ming Lin, West Harrison, NY (US); Chun-Yung Sung, Poughkeepsie, NY (US)

(72) Inventors: Xuesong Li, Yorktown Heights, NY (US); Yu-Ming Lin, West Harrison, NY (US); Chun-Yung Sung, Poughkeepsie, NY (US)

(21) Appl. No.: 13/454,113

(22) Filed: Apr. 24, 2012

(51) Int. Cl. C23C 16/455

(52) U.S. Cl. 427/255.28; 118/722; 118/724

(57) ABSTRACT

An apparatus for performing film deposition, comprises an energy source, a plurality of process tubes, and a gas manifold. The energy source is adapted to direct energy into a cylindrical space. The plurality of process tubes, in turn, pass through this cylindrical space. To perform the film deposition, the gas manifold is operative to introduce a respective gas flow into each of the plurality of process tubes.

### FIELD OF THE INVENTION

The present invention relates generally to apparatus and methods for chemical processing, and, more particularly, to tube-based reactors for chemical vapor deposition.

### BACKGROUND OF THE INVENTION

Chemical vapor deposition (CVD) is widely used in the semiconductor industry as well as other industries to form non-volatile solid-films on a substrate. In a typical CVD process, a given composition and flow of reactant gases are introduced into a reaction space where they are adsorbed onto a substrate. There, the reactants undergo migration and film-forming chemical reactions. The reaction by-products are then desorbed from the substrate and removed from the reaction space.

Furnace CVD systems (horizontal or vertical) are commonly utilized for CVD. In a typical furnace CVD system, the chemical reactants are flowed through a cylindrical quartz or alumina process tube that houses the substrate. The process tube, in turn, is surrounded by a heating furnace comprising resistance-heated heating elements (e.g., heating coils), which may be separated into zones to improve axial temperature uniformity. When properly designed, furnace CVD systems can achieve temperature uniformities of about one-half degree Centigrade (° C.) up to about 1,200° C.

Nevertheless, despite their widespread use, furnace CVD systems may suffer from several disadvantages. One way to improve throughput in a furnace CVD system, for example, is to increase the diameter of the process tube. However, both manufacturing costs and manufacturing errors increase when increasing process tube size. In addition, the roundness of the process tube may be compromised with greater process tube diameter, which may make it problematic to achieve a reliable vacuum seal with metal end-ports. Finally, the greater the size of the process tube, the more difficult it becomes to manage processing conditions therein.

For the foregoing reasons, there is a need for tube-based CVD systems that increase throughput while maintaining desirable footprint, energy efficiency, and deposition characteristics.

### SUMMARY OF THE INVENTION

Embodiments of the present invention address the above-identified needs by providing new apparatus for film deposition by CVD, as well as methods for their use. Advantageously, apparatus in accordance with aspects of the invention provide substantially greater throughput than conventional single-tube CVD reactors while not requiring that process tube diameters be substantially increased. At the same time, through the use of compact designs and the use of single heating sources, apparatus in accordance with aspects of the invention do not create a footprint that is substantially larger than a conventional single-tube CVD reactor nor do they consume a substantially greater amount of energy per run.

In accordance with an aspect of the invention, an apparatus for performing film deposition comprises an energy source, a plurality of process tubes, and a gas manifold. The energy source is adapted to direct energy into a cylindrical space. The plurality of process tubes, in turn, pass through this cylindrical space. To perform the film deposition, the gas manifold is operative to introduce a respective gas flow into each of the plurality of process tubes.

In accordance with another aspect of the invention, a method for performing film deposition comprises directing energy into a cylindrical space. A plurality of process tubes pass through this cylindrical space. To perform film deposition, a respective gas flow is introduced into each of the plurality of process tubes.

### BRIEF DESCRIPTION OF THE DRAWINGS

These and other features, aspects, and advantages of the present invention will become better understood with regard to the following description, appended claims, and accompanying drawings where:

FIG. 1A shows a side elevational view of a portion of a CVD tube reactor in accordance with a first illustrative embodiment of the invention;

FIG. 1B shows a sectional view of the FIG. 1A CVD tube reactor cut along the line B-B′ indicated in FIG. 1A;

FIG. 2A shows a block diagram of additional aspects of the FIG. 1A CVD tube reactor;

FIG. 2B shows a schematic diagram of at least a portion of one of the gas manifold sub-portions in the FIG. 1A CVD tube reactor;

FIG. 2C shows a schematic diagram of at least a portion of one of the exhaust manifold sub-portions in the FIG. 1A CVD tube reactor;

FIG. 3 shows a side elevational view of a portion of a CVD tube reactor in accordance with a second illustrative embodiment of the invention; and

FIG. 4 shows a side elevational view of a portion of a CVD tube reactor in accordance with a third illustrative embodiment of the invention.

### DETAILED DESCRIPTION OF THE INVENTION

The present invention will be described with reference to illustrative embodiments. For this reason, numerous modifications can be made to these embodiments and the results will still come within the scope of the invention. No limitations with respect to the specific embodiments described herein are intended or should be inferred.

The term “film deposition” as used herein is intended to encompass both what is commonly called film deposition and film growth. Thus, the term “film deposition” would include the forming of films that differ in composition and/or crystallinity from the respective substrates on which they are deposited, as well as the forming of films that substantially match the composition and crystallinity of the respective substrates on which they are deposited.

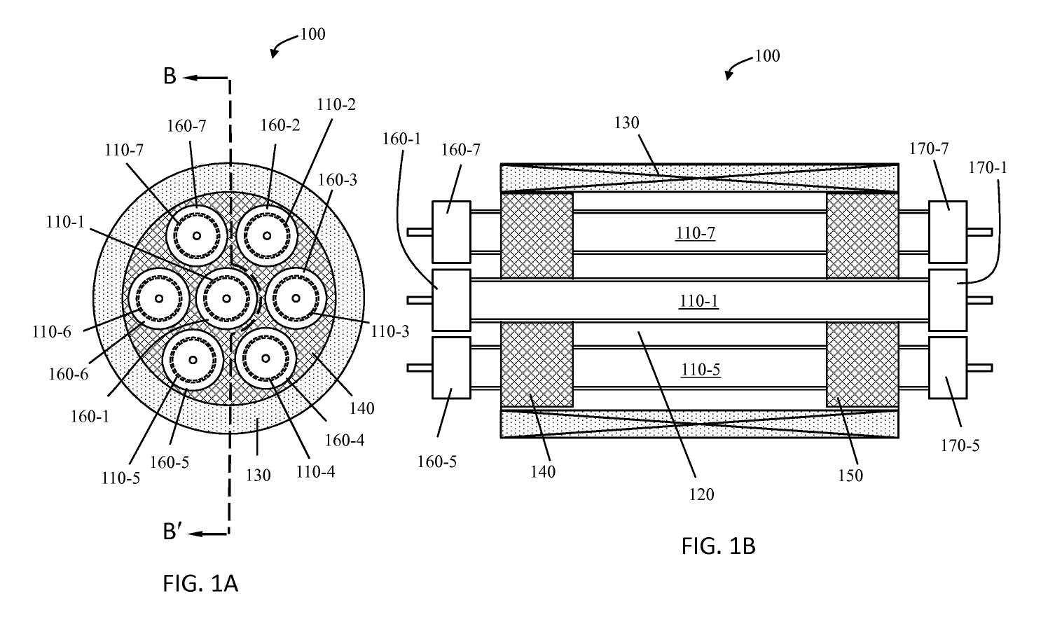

FIGS. 1A and 1B show at least a portion of a CVD tube reactor 100 in accordance with an illustrative embodiment of the invention. More particularly, FIG. 1A shows a side elevational view of the CVD tube reactor 100, while FIG. 1B shows a sectional view cut along the line B-B′ indicated in FIG. 1A. In this particular illustrative embodiment, the CVD tube reactor 100 comprises seven process tubes 110-n (where n is an integer in the range n=1 to n=7). Notably, while these process tubes 110-n are visible in FIG. 1A as dashed lines, they would, in actual reduction to practice, be hidden from view when the CVD tube reactor 100 is viewed from its ends.

In the CVD tube reactor 100, each of the process tubes 110-n passes through a cylindrical space 120 that is defined by a heating source 130, an input block 140, and an output block 150. The heating source 130 defines a wall of the cylindrical space 120 and is adapted to direct its energy into the cylindrical space 120. The input block 140 and the output block 150, in contrast, act to define the opposing ends of the cylindrical space 120 and, in doing so, act to trap the heat within the cylindrical space 120. The input block 140 and the output block 150 also act to physically support the process tubes 110-n. Such physical support is accomplished by having each of the input and output blocks 140, 150 define seven respective openings therein through which the process tubes 110-n pass.

Still referring to FIGS. 1A and 1B, each of the seven process tubes 110-n terminates in a respective input port 160-n and a respective output port 170-n. The input ports 160-n and the output ports 170-n are adapted to couple to the process tubes 110-n so as to form a vacuum seal therewith. Each of the input and output ports 160-n, 170-n, in turn, comprises a respective passage (e.g., vacuum feedthrough) that allows gases to pass through that particular port.

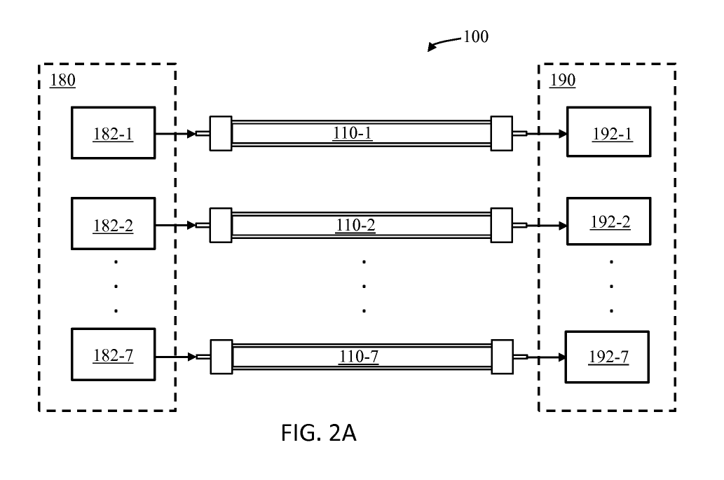

The CVD tube reactor 100 in the present illustrative embodiment is capable of performing film deposition by what is commonly called low-pressure CVD (LPCVD). When performing film deposition by LPCVD, reaction conditions are primarily determined by gas flow rates, pressure, and temperature, with pressure generally being set substantially below atmospheric pressure (e.g., about 0.25-2.0 Torr). FIGS. 2A shows a block diagram of additional aspects of the CVD tube reactor 100 that facilitate these kinds of LPCVD deposition processes. A gas manifold 180 introduces a respective gas flow into each of the process tubes 110-n. The gas flows emanating from the gas manifold 180 enter the process tubes 110-n through their respective input ports 160-n. At the opposite end of the process tubes 110-n, gases leaving the process tubes 110-n pass through their output ports 170-n into an exhaust manifold 190. Here, the exhaust manifold 190 regulates the respective pressures in each of the process tubes 110-n while pumping away the used gas flows.

Notably, the gas manifold 180 is operative to determine a different composition for each of the respective gas flows introduced into each of the plurality of process tubes 110-n, while the exhaust manifold 190 is operative to determine a different pressure for each of the plurality of process tubes 110-n. These capabilities allow different process conditions to be independently established in each of the process tubes 110-n during a single run of the CVD tube reactor 100. To facilitate such independent process control, both the gas manifold 180 and the exhaust manifold 190 in the CVD tube reactor 100 are partitioned into sub-portions so that a single process tube 110-n is serviced by a single respective gas manifold sub-portion and a single respective exhaust manifold sub-portion. Such partitioning is further shown in FIGS. 2A. The gas manifold 180 comprises a set of gas manifold sub-portions 182-n, each gas manifold sub-portion 182-n servicing a respective one of the plurality of process tubes 110-n. At the same time, the exhaust manifold 190 is also partitioned into a set of exhaust manifold sub-portions 192-n with each exhaust manifold sub-portion 192-n only servicing a single respective process tube 110-n.

FIG. 2B shows a schematic diagram of an exemplary one of the gas manifold sub-portions 182-n, in this case, the gas manifold sub-portion 182-1. In the present illustrative embodiment, the gas manifold sub-portion 182-1 comprises four process gas sources 200-m (where m is an integer in the range m=1 to m=4), although this particular number of process gas sources is largely arbitrary and a gas manifold sub-portion 182-n with a fewer or a greater number of process gas sources 200-m would still fall within the scope of the invention. Each process gas source 200-m is in fluid communication with a respective mass flow controller 210-m that acts to regulate the flow rate of the gas coming from that process gas source 200-m into the tube reactor 110-1.

FIG. 2C, in turn, shows a schematic diagram of one of the exhaust manifold sub-portions 192-n, more particularly, the exhaust manifold sub-portion 192-1. In the present illustrative embodiment, the gas flow, after leaving the process tube 110-1, passes a pressure sensor 220 before entering a throttle valve 230. The pressure sensor 220 measures the pressure in the process tube 110-1 and, via a conventional electronic feedback mechanism, controls the opening of the throttle valve 230 to regulate a preset pressure in the process tube 110-1. Once past the throttle valve 230, the gas flow is first pumped by a roots blower pump 240 and then by a rotary mechanical pump 250 before it is sent to an exhaust 260 (with a chemical scrubber if required).

As indicated above, the gas manifold sub-portion 182-1 shown in FIG. 2B and the exhaust manifold sub-portion 192-1 shown in FIG. 2C are replicated for each of the process tubes 110-n to provide independent process control for each of the process tubes 110-n. That said, however, it is recognized that several of the components shown in FIGS. 2B and 2C may be shared among several gas manifold sub-portions 182-n and exhaust manifold sub-portions 192-n, as the case may be, to aid in simplicity of the design. For example, it is contemplated that several of the gas manifold sub-portions 182-n might share common process gas sources 200-m, or that several of the exhaust manifold sub-portions 192-n may share a common roots blower pump 240 and/or a common rotary mechanical pump 250.

In fact, if independent process control for each of the process tubes 110-n is not required, it may not be necessary to partition the gas manifold 180 and the exhaust manifold 190 in the manner shown in FIG. 2A. Instead, a universal gas manifold 180 and a universal exhaust manifold 190 may be sufficient to service all of the process tubes 110-n, albeit without the advantages of individual process control described above. Despite this, the capability to individually control the process conditions in each of the process tubes 110-n is preferably, but not necessarily, included in order to at least address tube-to-tube temperature differences that may present themselves as the result of heating more than one process tube 110-n with the single heating source 130. It is recognized that the process tube 110-1 in the CVD tube reactor 100, for example, is farther from the heating source 130 than the remaining process tubes 110-2 to 110-7. As result, the temperature of the process tube 110-1 may be different (e.g., lower) than the others. The ability to independently control the process conditions in the various process tubes 110-n thereby becomes a convenient way to compensate for these kinds of temperature differences.

The various elements of the CVD tube reactor 100 may be formed from largely conventional materials. The process tubes 110-n in the CVD tube reactor 100 may, for example, comprise a material such as, but not limited to, quartz or alumina. At the same time, the input and output blocks 140, 150 may comprise any material having sufficient strength to support the process tubes 110-n and still be capable of withstanding high temperatures. Such materials may include, as just an example, refractory oxide materials such as alumina, which may be stable to temperatures greater than 1800° C. Finally, the input and output ports 160, 170 may comprise a metal such as aluminum or stainless steel, and may be vacuum coupled to the process tubes 110-n utilizing high-temperature o-ring seals formed of an elastomeric material such as perfluoroelastomer. If it is necessary to cool the input and the output ports 160, 170 to maintain the vacuum seal, they may be cooled by circulating cooling water, as is conventional.

The manner of forming the heating source 130, on the other hand, depends to a large degree on whether the walls of the process tubes 110-n are allowed to become relatively hot during processing, or whether, instead, it is desirable to keep the walls of the process tubes 110-n relatively cold during processing. Such a difference determines whether the CVD tube reactor 100 is configured as a “hot-wall” reactor or a “cold-wall” reactor. A cold-wall configuration reduces the rate of film deposition on the sidewalls of the process tubes 110-n, and thereby reduces the need to frequently clean the process tubes 110-n. In either case, several options are available for the heating source 130 that will fall within the scope of the invention. These options include, but are not limited to, resistance heating, radiant heating with high intensity radiation lamps, and electric induction heating. These heating options and other suitable options are described in a number of readily available publications, including A. C. Jones, Chemical Vapour Deposition: Precursors, Processes and Applications, Royal Society of Chemistry, 2009, which is hereby incorporated by reference herein. Whatever heating option is ultimately chosen, the heating source 130 preferably includes a suitable jacket or box (e.g., refractory metal oxide or fibrous refractory metal oxide) that helps to support the heating elements and to both thermally and electrically isolate the heating elements and the cylindrical space 120 from the environment outside the CVD tube reactor 100.

If a hot-wall reactor is acceptable, the heating source 130 may be formed utilizing resistively-heated heating elements that are energized by a voltage/current regulator. In one configuration, such resistively-heated heating elements may comprise, for example, one or more wires that are coiled around the cylindrical space 120 to form what is frequently called a “tube furnace.” If desired, several different coils may be arranged along the longitudinal axis of the cylindrical space 120 to create separately-controllable heating zones that can compensate for reactant depletion effects and so forth. For temperature regulation, signals from thermocouples in the CVD tube reactor 100 may be fed back to the voltage/current regulator so as to maintain a predetermined temperature set point.

If, on the other hand, a cold-wall reactor is desired, the heating source 130 may be configured utilizing high-intensity radiation lamps or radio frequency (rf) induction. To utilize high-intensity radiation lamps, the heating source 130 may be fitted with a multiplicity of radiation lamps (e.g., tungsten filament lamps) driven by a voltage/current regulator. Ideally, the radiation lamps will produce a light spectrum that effectively heats the contents of the process tubes 110-n (e.g., substrates and/or susceptors) by radiant heating while being transmitted through the walls of the process tubes 110-n with little absorption. Reflectors may be incorporated into the heating source 130 to help provide uniform illumination by the radiation lamps. Alternatively, the heating source 130 may be configured with one or more electric coils surrounding the cylindrical space 120 and driven by an rf generator. The electric coils may be configured as tubes capable of circulating a cooling liquid in order to facilitate their cooling. A strong magnetic field formed in the cylindrical space 120 thereby induces induction heating in any electrically conductive elements disposed in the process tubes 110-n (e.g., substrates and/or susceptors). Thermocouples and/or pyrometers may be used to feed back signals indicative of temperature to the voltage/current regulator or rf generator, as appropriate, to again maintain a predetermined temperature set point.

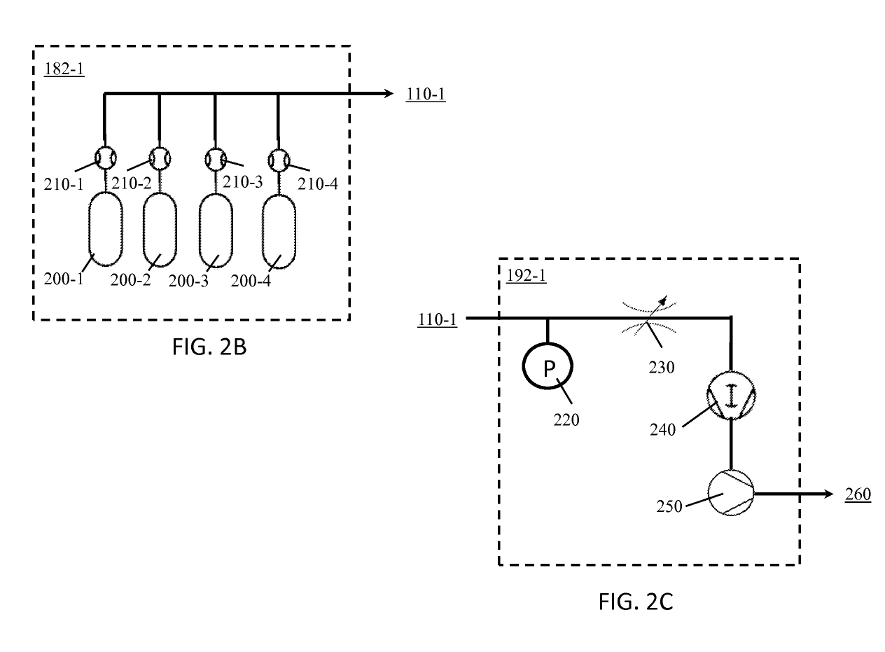

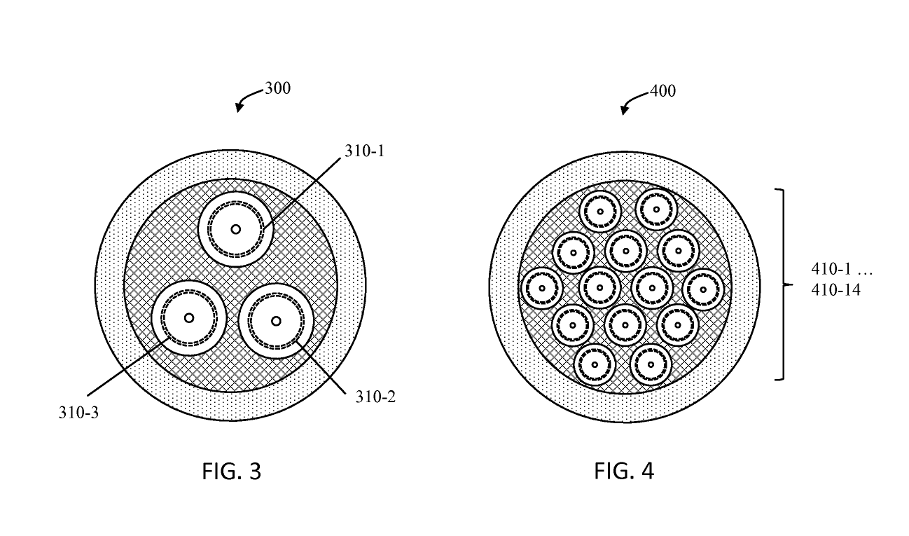

It should be noted that, while the CVD tube reactor 100 comprises seven process tubes 110-n, this number is largely arbitrary and other designs would also come within the scope of the invention. FIGS. 3 and 4 provide two additional exemplary embodiments in accordance with aspects of the invention for the purpose of stressing this point. FIG. 3, for example, shows a side elevational view of a portion of a CVD tube reactor 300 with three process tubes 310-1 to 310-3. FIG. 4, moreover, shows a side elevational view of a portion of a CVD tube reactor 400 with 14 process tubes 410-1 to 410-14. In all other respects, the CVD tube reactors 300, 400 are similar to the CVD tube reactor 100, meaning that they each comprise a respective heating source, a respective cylindrical space, respective input and output blocks, respective input and output ports for each of the process tubes, and so forth.

Embodiments in accordance with aspects of the invention provide a number of advantages over conventional single-tube CVD reactors. In providing more than one process tube within the heated cylindrical space, for example, “multi-tube” CVD tube reactors in accordance with aspects of the invention provide a much greater throughput than conventional single-tube CVD reactors. The CVD tube reactor 100, for example, with its seven process tubes 110-n, may accomplish in a single run what would take a conventional single-tube CVD reactor seven runs to realize. Notably, this increase in throughput is accomplished without the need to increase process tube diameter. Those issues associated with increasing the diameter of a process tube such as process tube defects, vacuum leaks, and poorly controlled processing conditions are thereby avoided. At the same time, through the use of a compact design and single heating source, the multi-tube CVD tube reactors do not create a footprint that is substantially larger than a conventional single-tube CVD reactor nor do they consume a substantially greater amount of energy per run.

In closing, it should again be emphasized that the above-described embodiments of the invention are intended to be illustrative only. Other embodiments can use different types and arrangements of elements for implementing the described functionality. These numerous alternative embodiments within the scope of the appended claims will be apparent to one skilled in the art. For example, the CVD tube reactor 100 described herein is one made suitable for LPCVD film deposition processes, meaning that the exhaust manifold 190 is capable of reducing the respective pressures in the plurality of process tubes 110-n substantially below atmospheric pressure. Nevertheless, this particular configuration is not intended to be a limitation on the scope of the invention. In one or more alternative embodiments of the invention, for example, CVD tube reactors in accordance with aspects of the invention may be configured for film deposition at atmospheric pressure, thereby facilitating atmospheric-pressure CVD (APCVD). Moreover, in one or more other alternative embodiments of the invention, CVD tube reactors falling within the scope of the invention may be fitted with electrodes capable of being energized by sources of rf energy to allow plasma-enhanced CVD (PECVD).

The features disclosed herein may be replaced by alternative features serving the same, equivalent, or similar purposes, unless expressly stated otherwise. Thus, unless expressly stated otherwise, each feature disclosed is one example only of a generic series of equivalent or similar features.

Any element in a claim that does not explicitly state “means for” performing a specified function or “step for” performing a specified function is not to be interpreted as a “means for” or “step for” clause as specified in 35 U.S.C. §112, ¶6. In particular, the use of “step of” in the claims herein is not intended to invoke the provisions of 35 U.S.C. §112, ¶6.

What is claimed is:

1. An apparatus for performing film deposition, the apparatus comprising:
an energy source, the energy source adapted to direct energy into a cylindrical space;
a plurality of process tubes, the plurality of process tubes passing through the cylindrical space; and
a gas manifold, the gas manifold operative to introduce a respective gas flow into each of the plurality of process tubes.

2. The apparatus of claim 1, wherein the energy source defines a wall of the cylindrical space.

3. The apparatus of claim 1, wherein the energy source comprises a resistively-heated heating element.

4. The apparatus of claim 3, wherein the resistively-heated heating element forms a coil around the cylindrical space.

5. The apparatus of claim 1, wherein the energy source comprises one or more heating lamps.

6. The apparatus of claim 1, wherein the energy source comprises an electrical coil operative to direct a magnetic field into the cylindrical space.

7. The apparatus of claim 1, wherein the energy source comprises a plurality of separately controllable zones.

8. The apparatus of claim 1, wherein each of the plurality of process tubes terminates in a respective input port and a respective output port.

9. The apparatus of claim 8, wherein each of the input ports comprises a respective passage adapted to allow gases to be passed through the input port.

10. The apparatus of claim 8, wherein each of the output ports comprises a respective passage adapted to allow gases to be passed through the output port.

11. The apparatus of claim 1, wherein each of the plurality of process tubes comprises at least one of quartz and alumina.

12. The apparatus of claim 1, wherein the gas manifold is operative to determine a different respective composition for each of the respective gas flows introduced into each of the plurality of process tubes.

13. The apparatus of claim 1, wherein the gas manifold comprises one or more mass flow controllers.

14. The apparatus of claim 1, further comprising a first support block, the first support block defining a plurality of openings therein through which the plurality of process tubes pass.

15. The apparatus of claim 14, further comprising a second support block, the second support block defining a plurality of openings therein through which the plurality of process tubes pass, the second support block being spaced apart from the first support block.

16. The apparatus of claim 15, wherein the first support block and the second support block define opposing ends of the cylindrical space.

17. The apparatus of claim 1, further comprising an exhaust manifold, the exhaust manifold operative to determine a different respective pressure for each of the plurality of process tubes.

18. The apparatus of claim 17, wherein the exhaust manifold is operative to reduce the respective pressures in each of the plurality of process tubes below atmospheric pressure.

19. The apparatus of claim 17, wherein the exhaust manifold comprises one or more vacuum pumps.

20. A method for performing film deposition, the method comprising the steps of:
directing energy into a cylindrical space through which a plurality of process tubes pass; and
introducing a respective gas flow into each of the plurality of process tubes.
